(19) United States
(12) Patent Application Publication
(10) Pub. No.: US 2026/0206175 A1
(43) Pub. Date: Jul. 16, 2026

(54) HEAT MITIGATION ASSEMBLY FOR AN INFORMATION HANDLING SYSTEM

(71) Applicant: Dell Products L.P., Round Rock, TX (US)

(72) Inventor: Qinghong He, Austin, TX (US)

(21) Appl. No.: 19/021,484

(22) Filed: Jan. 15, 2025

(51) Int. Cl. H05K 7/20; G06F 1/20

(52) U.S. Cl. CPC H05K 7/20172; G06F 1/20; H05K 7/20336

(57) ABSTRACT

An information handling system, including a first body, the first body including: a heat mitigation assembly isolated from remaining portions of the information handling system, the heat mitigation assembly including: a fan casing including a walled perimeter that encases the fan casing; a fan contained within the walled perimeter of the fan casing, the fan including a plurality of fan blades; and a portion of a heat pipe contained within the walled perimeter of the fan casing such that the portion of the heat pipe is between the walled perimeter and the fan blades.

### BACKGROUND

### Field of the Disclosure

The disclosure relates generally to an information handling system, and in particular, a heat mitigation assembly for the information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Fans in information handling assemblies are essential for maintaining optimal temperatures by dissipating heat generated by components like the CPU and GPU. They come in various sizes and speeds, tailored to different cooling needs and noise preferences. Proper fan placement and airflow management can significantly enhance a computer’s performance and longevity.

### SUMMARY

Innovative aspects of the subject matter described in this specification may be embodied in an information handling system, including a first body, the first body including a heat mitigation assembly isolated from remaining portions of the information handling system, the heat mitigation assembly including a fan casing including a walled perimeter that encases the fan casing; a fan contained within the walled perimeter of the fan casing, the fan including a plurality of fan blades; and a portion of a heat pipe contained within the walled perimeter of the fan casing such that the portion of the heat pipe is between the walled perimeter and the fan blades.

Other embodiments of these aspects include corresponding systems and apparatus.

These and other embodiments may each optionally include one or more of the following features. For instance, the portion of the heat pipe is proximate to the plurality of fan blades of the fan. The fan casing includes a first surface and a second surface opposite to the first surface, wherein the walled perimeter is positioned between the first surface and the second surface. The portion of the heat pipe is positioned proximate to the first surface of the fan casing. An air gap is defined between the portion of the heat pipe and the second surface of the fan casing. The fan is configured to move air through the air gap. The heat mitigation assembly further including a heat sink in thermal communication with the portion of the heat pipe.

Particular implementations of the subject matter described in this specification can be implemented so as to realize one or more of the following advantages. For example, the invention provides an increased fan blade size leading to increased airflow movement by the fan, and increased operating temperatures by computing components and higher processing parameters of the information handling system.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a simplified side view of the information handling system.

FIG. 3 illustrates a block diagram of the information handling system for including a heat mitigation assembly.

FIG. 4 illustrates a perspective view of the heat mitigation assembly.

FIG. 5 illustrates a top-down view of the heat mitigation assembly.

FIG. 6 illustrates a perspective side view of the heat mitigation assembly along the line A-A’ of FIG. 4.

FIG. 7 is a side view of the heat mitigation assembly along the line A-A’ of FIG. 4.

### DESCRIPTION OF PARTICULAR EMBODIMENTS

This disclosure discusses an information handling system including a heat mitigation assembly. In short, a heat mitigation assembly can include at least a portion of a heat pipe being included by a fan casing. That is, the portion of the heat pipe and the fan can coexist within the fan casing. The heat pipe can be routed proximate to a perimeter of the fan casing such that a size of fan blades of the fan can be maximized for the fan casing. Additionally, an air gap defined below the heat pipe can be utilized for internal airflow movement, described further herein.

Specifically, this disclosure discusses an information handling system, including a first body, the first body including: a heat mitigation assembly isolated from remaining portions of the information handling system, the heat mitigation assembly including: a fan casing including a walled perimeter that encases the fan casing; a fan contained within the walled perimeter of the fan casing, the fan including a plurality of fan blades; and a portion of a heat pipe contained within the walled perimeter of the fan casing such that the portion of the heat pipe is between the walled perimeter and the fan blades.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

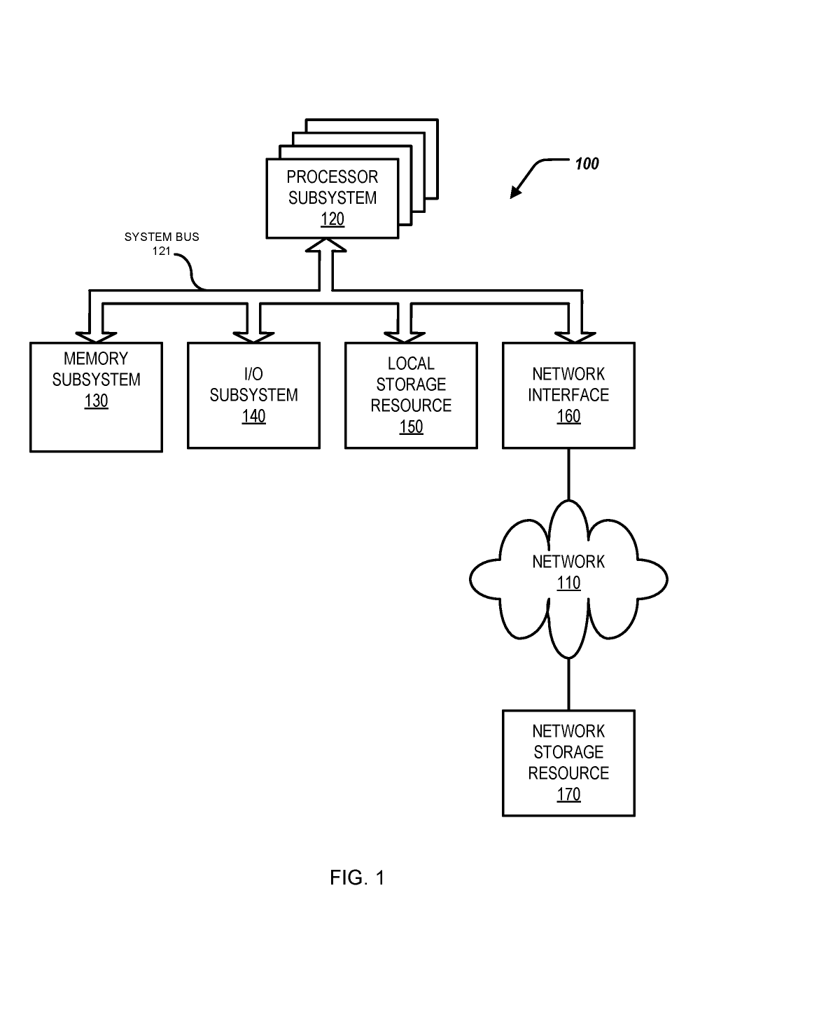

Particular embodiments are best understood by reference to FIGS. 1-7 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

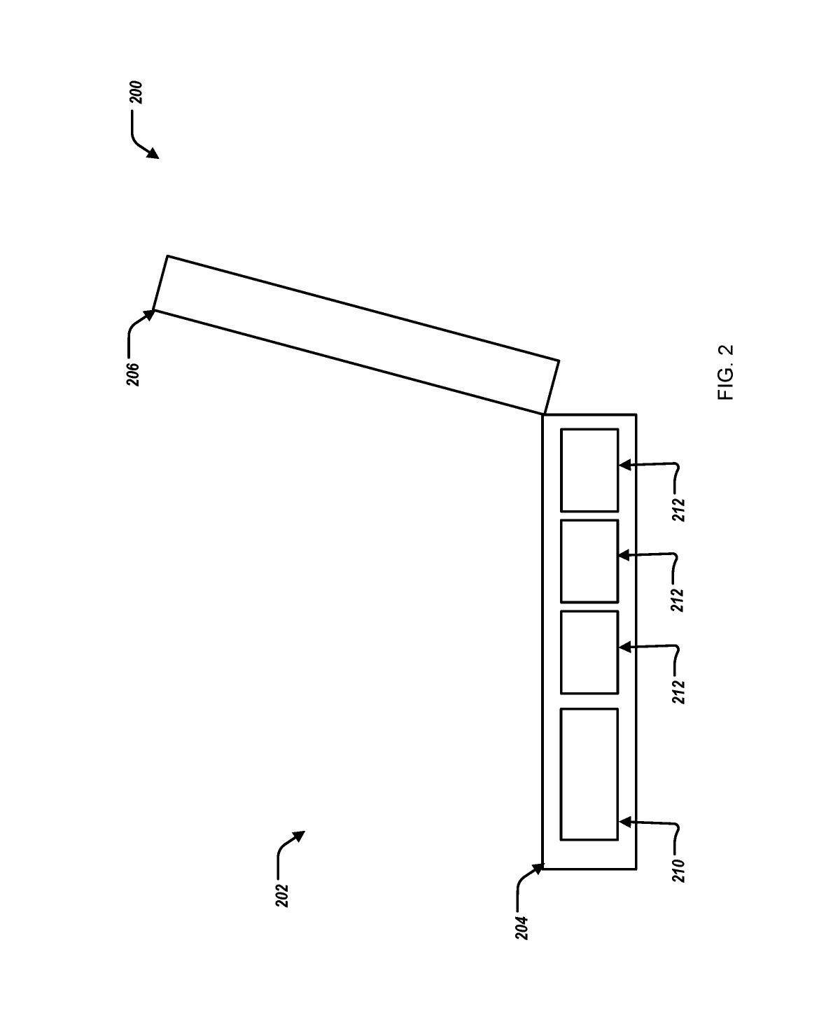

FIG. 2 illustrates a perspective view of an environment 200 including the information handling system 202, in an open state. The information handling system 202 can include a first body 204 and a second body 206. A hinge can couple the first body 204 to the second body 206. In some examples, the information handling system 202 is similar to, or includes, the information handling system 100 of FIG. 1. The first body 204 includes a heat mitigation assembly 210 and computing components 212. The computing components 212 can include any computing module, such as a CPU, GPU, memory, and the like. The heat mitigation assembly 210 is isolated from remaining portions of the information handling system 202. That is, the heat mitigation assembly 210 is isolated from the computing components 212. In some examples, the heat mitigation assembly 210 is physically isolated from the remaining portions of the information handling system 202, including being physically isolated from the computing components 212.

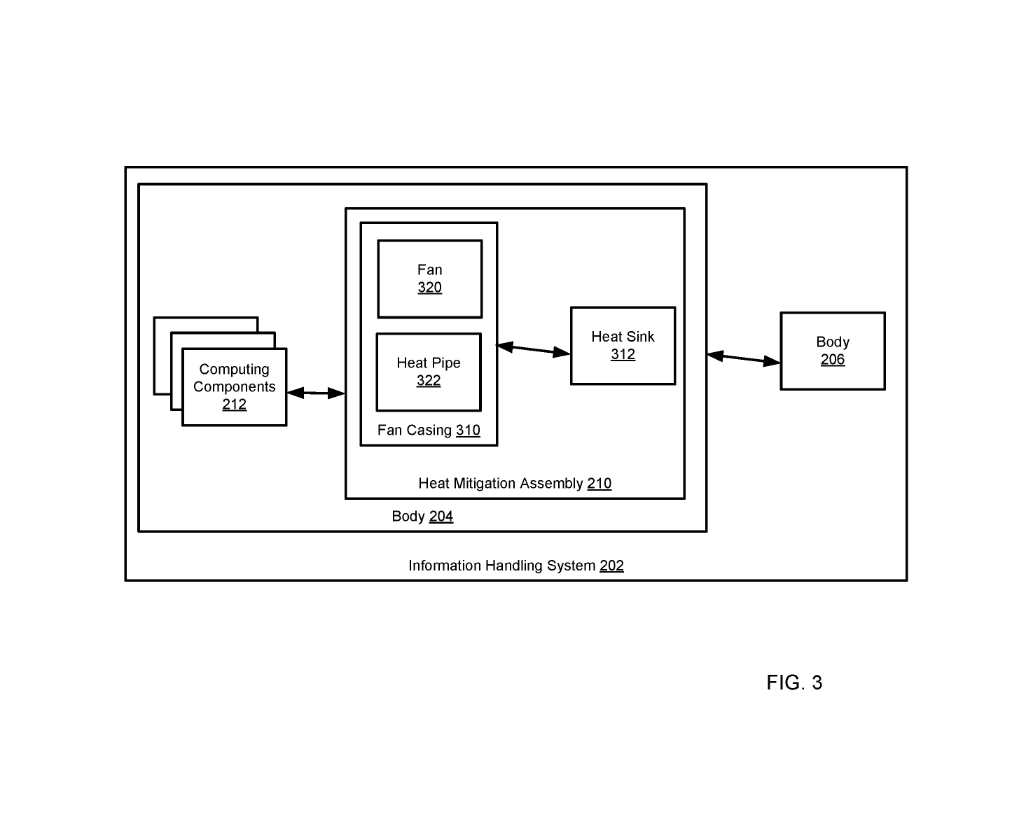

Turning to FIG. 3, FIG. 3 illustrates the information handling system 202. The information handling system 202 can include the first body 204 and the second body 206. The first body 204 can include the heat mitigation assembly 210 and the computing components 212. The heat mitigation assembly 210 can include a fan casing 310 and a heat sink 312. The fan casing 310 can include a fan 320 and a heat pipe 322.

The heat mitigation assembly 210 can be in thermal communication with the computing components 212. The fan casing 310 can be in thermal communication with the heat sink 312.

In short, the heat mitigation assembly 210 can include at least a portion of the heat pipe 322 being included by the fan casing 310. That is, the portion of the heat pipe 322 and the fan 320 can coexist within the fan casing 310. The heat pipe 322 can be routed proximate to a perimeter of the fan casing such that a size of fan blades of the fan 320 can be maximized for the fan casing 310. Additionally, an air gap defined below the heat pipe 322 can be utilized for internal airflow movement, described further herein.

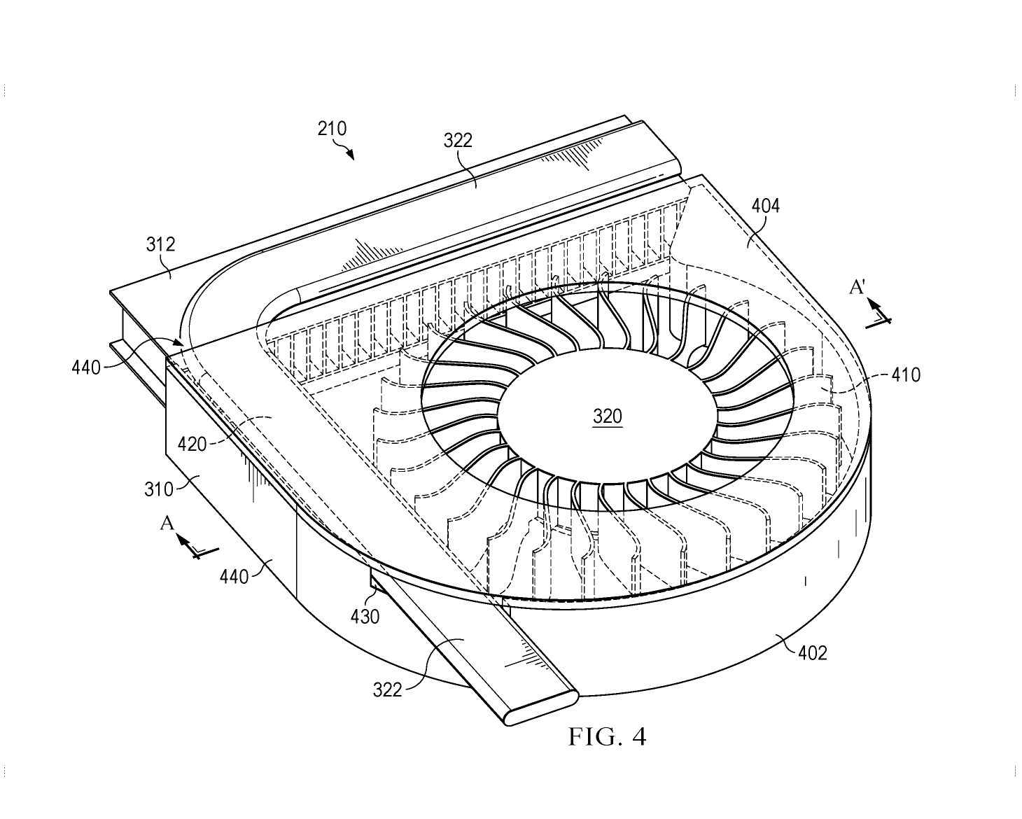

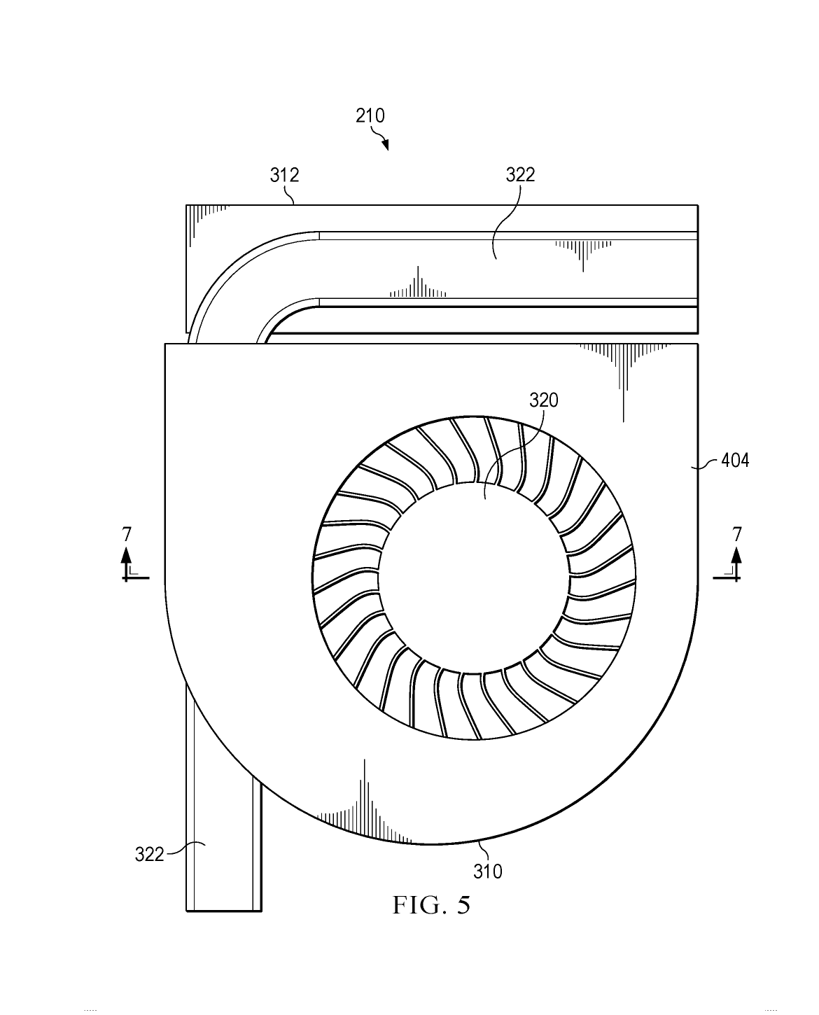

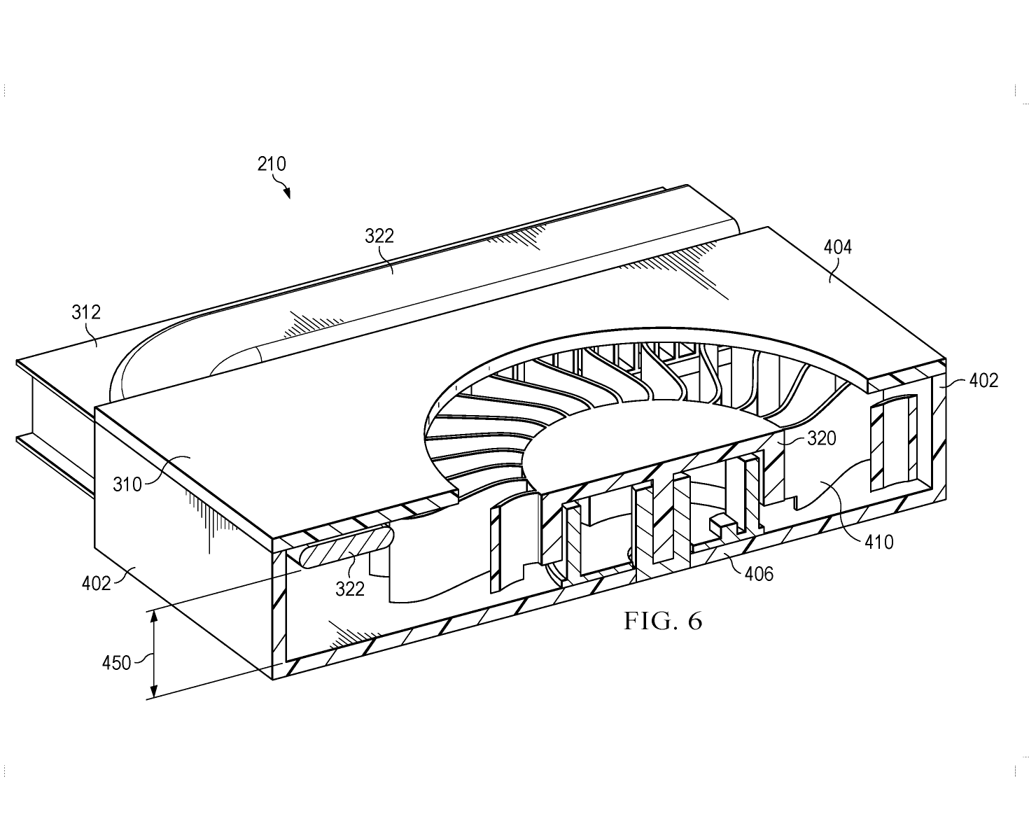

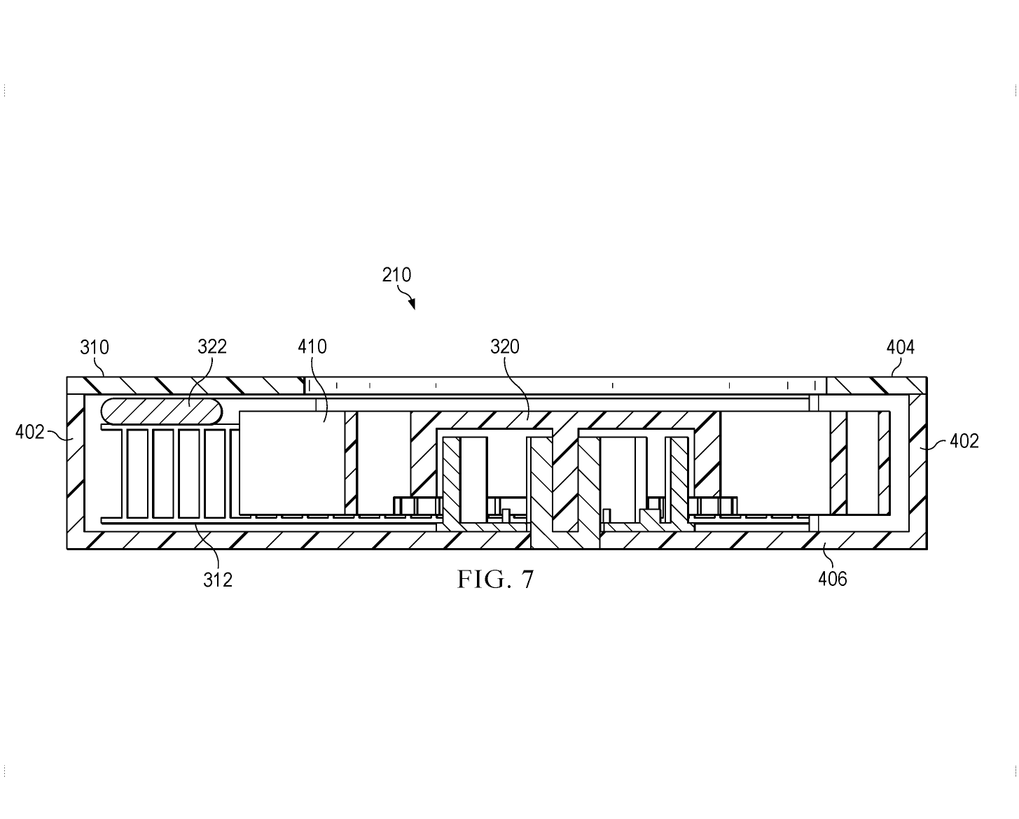

FIG. 4 illustrates a perspective partially transparent view of the heat mitigation assembly 210; FIG. 5 illustrates a top down view of the heat mitigation assembly 210; FIG. 6 illustrates a perspective side view of the heat mitigation assembly 210 along the line A-A’ of FIG. 4; and FIG. 7 is a side view of the heat mitigation assembly 210 along the line A-A’ of FIG. 4.

Referring to FIGS. 4-7, the heat mitigation assembly 210 includes the fan casing 310. The fan casing 310 can include a first surface 404 and a second surface 406. The second surface 406 is opposite to the first surface 404. The fan casing 310 can further include a walled perimeter 402 that is positioned between the first surface 404 and the second surface 406. In some examples, the walled perimeter 402 encases the fan casing 310. In some examples, the walled perimeter 402 completely encases the fan casing 310. In some examples, the walled perimeter substantially encases the fan casing 310. In some examples, the walled perimeter 402 partially encases the fan casing 310.

The heat mitigation assembly 210 further includes the fan 320. The fan 320 is contained within the walled perimeter 402 of the fan casing 310. The fan 320 can be completely contained within the fan casing 310. The fan 320 includes a plurality of fan blades 410.

The heat mitigation assembly 210 further includes a portion 420 of the heat pipe 322. The portion 420 of the heat pipe 322 is contained within the walled perimeter 402 of the fan casing 310. Specifically, the portion 420 of the heat pipe 322 is contained within the walled perimeter 402 of the fan casing 310 such that the portion 420 of the heat pipe 322 is between the walled perimeter 402 and the fan blades 410. In other words, the portion 420 of the heat pipe 322 and the fan 320 (and fan blades 410) coexist within the fan casing 310 (within one fan casing).

The fan casing 310, and in particular the walled perimeter 402, can include a first opening 430 and a second opening 440. The heat pipe 322 can be positioned through the first opening 430 and the second opening 440 such that the portion 420 of the heat pipe 322 is positioned within the fan casing 310 and within the walled perimeter 402. That is, the portion 420 of the heat pipe 322 is positioned between the first opening 430 and the second opening 440 of the fan casing 310.

The portion 420 of the heat pipe 322 is proximate to the first surface 404 of the fan casing 310. However, in some examples, the portion 420 of the heat pipe 322 can be proximate to the second surface 406 of the fan casing 310. In some further examples, the portion 420 of the heat pipe 322 can extend between the first surface 404 and the second surface 406 of the fan casing 310.

The portion 420 of the heat pipe 322 is proximate to the plurality of fan blades 410 of the fan 320. Further, the portion 420 of the heat pipe 322 can be proximate to a portion 420 of the walled perimeter 402. That is, the portion 420 of the heat pipe 322 is positioned between the fan blades 410 of the fan 320 and the portion 420 of the wall perimeter 402. Thus, by routing the portion 420 of the heat pipe 322 proximate to the portion 420 of the wall perimeter 402 (the heat pipe 322 is routed “close” to the wall perimeter 402), the fan blades 410 of the fan 320 are maximized given the available size of the fan casing 310 to be proximate to the portion 420 of the heat pipe 322 (the fan blades 410 are at a maximum size for the fan casing 310 by being “close” to the heat pipe 322).

In some examples, by the portion 420 of the heat pipe 322 is proximate to the first surface 404 of the fan casing 310, an air gap 450. That is, an air gap 450 is defined between the portion 420 of the heat pipe 322 and the second surface 406 of the fan casing 310. Further, the air gap 450 is defined between the walled perimeter 402 and the fan blades 410. To that end, the heat mitigation assembly 210, and in particular, the fan 320, is configured to move air through the air gap 450. That is, the fan 320 utilizes the air gap 450 for internal airflow movement.

The heat mitigation assembly 210 further includes the heat sink 312. The heat sink 312 is in thermal communication with the heat pipe 322. Specifically, the heat sink 312 is in thermal communication with the heat pipe 322, and in particular, the portion 420 of the heat pipe 322. To that end, the heat pipe 322 can draw heat (thermal energy) from the computing components 212 (shown in FIGS. 2-3), and transmit the heat (thermal energy) from the heat pipe 322 to the heat sink 312 via the fan 320 utilizing the air gap 450.

In a use case, when the fan blades 410 of the fan 320 is 42 millimeters, at 45 degrees Celsius ambient, the information handling system 202 is able to support 17 Watts of CPU power.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system, comprising:
a first body, the first body including:
a heat mitigation assembly isolated from remaining portions of the information handling system, the heat mitigation assembly including:
a fan casing including a walled perimeter that encases the fan casing;
a fan contained within the walled perimeter of the fan casing, the fan including a plurality of fan blades; and
a portion of a heat pipe contained within the walled perimeter of the fan casing such that the portion of the heat pipe is between the walled perimeter and the fan blades.

2. The information handling system of claim 1, wherein the portion of the heat pipe is proximate to the plurality of fan blades of the fan.

3. The information handling system of claim 1, wherein the fan casing includes a first surface and a second surface opposite to the first surface, wherein the walled perimeter is positioned between the first surface and the second surface.

4. The information handling system of claim 3, wherein the portion of the heat pipe is positioned proximate to the first surface of the fan casing.

5. The information handling system of claim 4, wherein an air gap is defined between the portion of the heat pipe and the second surface of the fan casing.

6. The information handling system of claim 5, wherein the fan is configured to move air through the air gap.

7. The information handling system of claim 1, the heat mitigation assembly further including a heat sink in thermal communication with the portion of the heat pipe.

8. A heat mitigation assembly for an information handling system, comprising:
a fan casing including a walled perimeter that encases the fan casing;
a fan contained within the walled perimeter of the fan casing, the fan including a plurality of fan blades; and
a portion of a heat pipe contained within the walled perimeter of the fan casing such that the portion of the heat pipe is between the walled perimeter and the fan blades,
wherein the heat mitigation assembly is isolated from remaining portions of the information handling system.

9. The heat mitigation assembly of claim 8, wherein the portion of the heat pipe is proximate to the plurality of fan blades of the fan.

10. The heat mitigation assembly of claim 8, wherein the fan casing includes a first surface and a second surface opposite to the first surface, wherein the walled perimeter is positioned between the first surface and the second surface.

11. The heat mitigation assembly of claim 10, wherein the portion of the heat pipe is positioned proximate to the first surface of the fan casing.

12. The heat mitigation assembly of claim 11, wherein an air gap is defined between the portion of the heat pipe and the second surface of the fan casing.

13. The heat mitigation assembly of claim 12, wherein the fan is configured to move air through the air gap.

14. The heat mitigation assembly of claim 8, the heat mitigation assembly further including a heat sink in thermal communication with the portion of the heat pipe.

15. An information handling system, comprising:
a first body, the first body including:
computing components;
a heat mitigation assembly isolated from remaining portions of the information handling system, the heat mitigation assembly including:
a fan casing including a walled perimeter that encases the fan casing;
a fan contained within the walled perimeter of the fan casing, the fan including a plurality of fan blades; and
a portion of a heat pipe contained within the walled perimeter of the fan casing such that the portion of the heat pipe is between the walled perimeter and the fan blades,
wherein the heat mitigation assembly is configured to mitigate heat generated by the computing components.

16. The information handling system of claim 15, wherein the portion of the heat pipe is proximate to the plurality of fan blades of the fan.

17. The information handling system of claim 15, wherein the fan casing includes a first surface and a second surface opposite to the first surface, wherein the walled perimeter is positioned between the first surface and the second surface.

18. The information handling system of claim 17, wherein the portion of the heat pipe is positioned proximate to the first surface of the fan casing.

19. The information handling system of claim 18, wherein an air gap is defined between the portion of the heat pipe and the second surface of the fan casing.

20. The information handling system of claim 19, wherein the fan is configured to move air through the air gap.
